(19) United States
(12) Patent Application Publication
(10) Pub. No.: US 2026/0247637 A1
(43) Pub. Date: Aug. 20, 2026

(54) CAPACITOR INCLUDING NITRIDE-BASED ELECTRODE, METHOD OF MANUFACTURING THE SAME, SEMICONDUCTOR DEVICE INCLUDING THE CAPACITOR, AND ELECTRONIC DEVICE

(71) Applicant: Samsung Electronics Co., Ltd., Suwon-si (KR)

(72) Inventors: Hyungjun KIM, Suwon-si (KR); Haeryong KIM, Suwon-si (KR); Euncheol DO, Suwon-si (KR); Boeun PARK, Suwon-si (KR); Jeongil BANG, Suwon-si (KR); Jaeho LEE, Suwon-si (KR)

(73) Assignee: Samsung Electronics Co., Ltd., Suwon-si (KR)

(21) Appl. No.: 19/322,099

(22) Filed: Sep. 8, 2025

(30) Foreign Application Priority Data
Feb. 14, 2025 (KR) 10-2025-0019650

(51) Int. Cl. H10D 1/68; H10D 1/00

(52) U.S. Cl. CPC H10D 1/692; H10D 1/042

(57) ABSTRACT

Provided are a capacitor including a nitride-based electrode, a method of manufacturing the same, and a semiconductor device and an electronic device each including the capacitor. The method of manufacturing the capacitor according to at least one example embodiment includes forming an interfacial layer on a first electrode layer and reducing the interfacial layer. Next, a dielectric layer is formed on the reduced interfacial layer, and a second electrode layer is formed. The first electrode layer includes a nitride-based electrode. The interfacial layer may include metal having an oxidation property greater than that included in the first electrode layer.

### CROSS-REFERENCE TO RELATED APPLICATION

This application is based on and claims priority under 35 U.S.C. §119 to Korean Patent Application No. 10-2025-0019650, filed on Feb. 14, 2025, in the Korean Intellectual Property Office, the disclosure of which is incorporated by reference herein in its entirety.

### BACKGROUND

### 1. Field

The present disclosure relates to a device including a nitride-based electrode and a method of manufacturing the same, and in particular, to a capacitor including a nitride-based electrode, a method of manufacturing the same, a semiconductor device including the capacitor, and an electronic device.

### 2. Description of the Related Art

As the degree of integration of semiconductor devices increases, the area in which elements of the devices are formed are also being reduced. Accordingly, since capacitance is inversely related to the area of the components therein, one of the methods of improving the capacitance in such elements is to use a dielectric material having a relatively high dielectric constant in order to compensate for the reduction in area.

In order to overcome limitations of existing binary-oxide dielectrics, perovskite materials having a relatively high dielectric constant of 100 or greater are being considered.

However, the perovskite material may have a low band gap, and thus a leakage current may increase. In addition, the conditions for processing of the perovskite materials may relatively harsh, and may increase damage other components of the elements. For example, the perovskite material may undergo a relatively high-temperature thermal process in order to improve the crystallinity of the perovskite material, but which may degrade other components of the element. Additionally, a deposition process for the perovskite material may be performed under a deposition condition applying a relatively strong oxidizing atmosphere, and thus, a countermeasure for protecting against oxidation of a lower electrode may be applied.

### SUMMARY

According to at least one example embodiment, provided is a capacitor having a relatively high capacitance density.

According to at least one example embodiment, provided is a capacitor capable of protecting against oxidation of a lower electrode.

According to at least one example embodiment, provided is a method of manufacturing the capacitor.

According to at least one example embodiment, provided is a semiconductor device including the capacitor.

According to at least one example embodiment, provided is an electronic device including the capacitor and/or the semiconductor device.

Additional aspects will be set forth in part in the description which follows and, in part, will be apparent from the description, or may be learned by practice of the presented embodiments of the disclosure.

According to at least one example embodiment, a method of manufacturing a capacitor includes forming an interfacial layer on a first electrode layer, the first electrode layer including a nitride-based electrode; removing oxygen from the interfacial layer by reducing the interfacial layer; forming a dielectric layer on the interfacial layer that was reduced; and forming a second electrode layer on the dielectric layer.

In an example, the forming of the dielectric layer includes depositing the dielectric layer on the reduced interfacial layer and crystallizing the deposited dielectric layer.

In an example, the depositing of the dielectric layer may be performed at a temperature of about 300° C. to about 400° C. under an oxygen atmosphere, the oxygen atmosphere including H₂O₂, H₂O, O₂ or O₃.

In an example, the forming the dielectric layer includes forming the dielectric layer such that the dielectric layer is 20% or less amorphous.

In an example, the reducing of the interfacial layer may include performing a first thermal treatment on the interfacial layer. In an example, the first thermal treatment may be executed under a gas atmosphere including hydrogen and at least one of argon (Ar) and nitrogen (N₂).

In an example, the forming the dielectric layer may include oxidizing the interfacial layer that was reduced, and the dielectric layer may be formed to a thickness such that the interfacial layer that was reduced is completely oxidized.

In an example, the interfacial layer may include a first dielectric layer having a dielectric constant that is less than a dielectric constant of the dielectric layer.

In an example, the interfacial layer may include a second metal having a higher oxidation property than a first metal included in the first electrode layer. In an example, the first metal may include at least one of Ti, Nb, V, Mo, Mn, W, or Ru, and the second metal may include at least one of Y or Sc.

According to at least one example embodiment, a capacitor includes a nitride-based lower electrode layer, an upper electrode layer; and a dielectric layer between the lower electrode layer and the upper electrode layer, the dielectric layer comprising a first dielectric layer in contact with the lower electrode layer, and a second dielectric layer on the first dielectric layer such that the first dielectric layer is between the second dielectric layer and the lower electrode layer, the second dielectric layer having a dielectric constant greater than a dielectric constant of the first dielectric layer.

The first dielectric layer is an interfacial layer, and the second dielectric layer may be a crystallized layer and is 20% or less amorphous.

In an example, the first dielectric layer may include oxygen vacancies in a region adjacent to the lower electrode layer.

In an example, the lower electrode layer may include a first metal, the first dielectric layer may include a second metal, the second metal may have an oxidation property greater than the first metal. In an example, the first metal may include at least one of Ti, Nb, V, Mo, Mn, W, and Ru, and the second metal may include at least one of Y and Sc.

According to at least one example embodiment, an electronic device includes a switching device, and a data storage element connected to the switching device. The data storage element may include a nitride-based lower electrode layer connected to the switching device, an upper electrode layer, and a dielectric layer between the upper electrode layer and the lower electrode layer. The dielectric layer may include a first dielectric layer in contact with the lower electrode layer, and a second dielectric layer on the first dielectric layer such that the first dielectric layer is between the second dielectric layer and the lower electrode layer. The second dielectric layer may have a dielectric constant greater than a dielectric constant of the first dielectric layer. The first dielectric layer may be an interfacial layer, and the second dielectric layer may be a crystallized layer and may be 20% or less amorphous.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a first capacitor including a nitride-based electrode, according to at least one example embodiment;

FIG. 2 is a cross-sectional view of a second capacitor including a nitride-based electrode, according to at least one example embodiment;

FIGS. 3 to 11 are cross-sectional views illustrating processes of a method of manufacturing a capacitor including a nitride-based electrode, according to at least one example embodiment;

FIG. 12 is a graph showing an X-ray Photoelectron Spectroscopy (XPS) analysis result for a Y₂O₃ film that is thermally treated to induce reduction at a temperature of 300° C. to 700° C. in a first experiment;

FIG. 13 is a transmission electron microscope (TEM) picture of a Y₂O₃ film that is thermally treated to induce reduction at a temperature of 600° C. in a first experiment;

FIG. 14 is a graph showing a transmission electron microscope-energy dispersive X-ray spectroscopy (TEM-EDS) analysis result to identify a composition distribution of a TiN electrode and Y₂O₃ film that are thermally treated to induce reduction at a temperature of 600° C. in a first experiment;

FIG. 15 is a graph showing capacitance densities measured with respect to capacitors of a metal-insulator-metal (MIM) type that use a TiN electrode as a lower electrode, a SrTiO₃ (STO) film as a dielectric substance, and a RuO₂ electrode as an upper electrode in the first experiment;

FIG. 16A, FIG. 16B, and FIG. 16C are TEM photographs of a first sample capacitor and second and third sample capacitors in which a Y₂O₃ film is formed to a thickness of 20 Å;

FIG. 17 is a graph showing an XPS analysis result for a Sc₂O₃ film that is thermally treated to induce reduction at a temperature of 300° C. to 700° C. in a second experiment;

FIG. 18 is a TEM photograph of Sc₂O₃ film that is thermally treated to induce reduction at a temperature of 600° C. in a second experiment;

FIG. 19 is a graph showing a TEM-EDS analysis result to identify composition distributions on a TiN electrode and Sc₂O₃ film that are thermally treated to induce reduction at a temperature of 600° C. in the second experiment;

FIG. 20 is a graph showing capacitance densities measured with respect to capacitors of a MIM type that use a TiN electrode as a lower electrode, an STO film as a dielectric substance, and a RuO₂ electrode as an upper electrode in the second experiment;

FIG. 21 is a schematic diagram of a semiconductor device according to at least one example embodiment;

FIG. 22 is a block diagram of an electronic system according to at least one example embodiment;

FIG. 23 is a conceptual diagram schematically showing device architectures applied to an electronic device, according to at least one example embodiment;

FIG. 24 is a block diagram of a memory system according to at least one example embodiment; and

FIG. 25 is a block diagram showing a neuromorphic device and an external device connected to the neuromorphic device according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a capacitor including a nitride-based electrode, a method of manufacturing the same, and a semiconductor device and an electronic device including the capacitor according to at least one example embodiment are described in detail with reference to accompanying drawings. Thickness of layers and regions illustrated in the drawings are exaggerated for convenience of description.

The embodiments of the disclosure are capable of various modifications and may be embodied in many different forms. In a layer structure described below, an expression such as “above” or “on” may include not only the meaning of immediately on in a contact manner, but also the meaning of on in a non-contact manner. In the description below, like reference numerals denote same members. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical and/or geometric values.

Singular forms include plural forms unless apparently indicated otherwise contextually. It will be further understood that when a portion is referred to as “comprising” another component, the portion may not exclude another component but may further comprise another component unless the context states otherwise. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

The use of the term of “the above-described” and similar indicative terms may correspond to both the singular forms and the plural forms. Also, the steps of all methods described herein may be performed in any suitable order unless otherwise indicated herein or otherwise clearly contradicted by context. The present disclosure is not limited to the described order of the steps.

Also, the use of terms like “ . . . unit”, “ . . . module”, etc., which are used herein specify a unit for processing at least one function or operation, may be implemented with and/or include processing circuitry such as hardware or software or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Also, connecting lines or connecting members illustrated in the drawings are intended to represent example functional relationships and/or physical or logical connections between the various elements. It should be noted that many alternative or additional functional relationships, physical connections or logical connections may be present in a practical device.

Furthermore, the connecting lines or connectors shown in the drawings are intended to represent example functional relationships and/or physical or logical couplings between the various elements. It should be noted that many alternative or additional functional relationships, physical connections, or logical connections may be present in a practical device.

The use of any and all examples, or example language provided herein, is intended merely to better illuminate the present disclosure and does not pose a limitation on the scope of the present disclosure unless otherwise claimed.

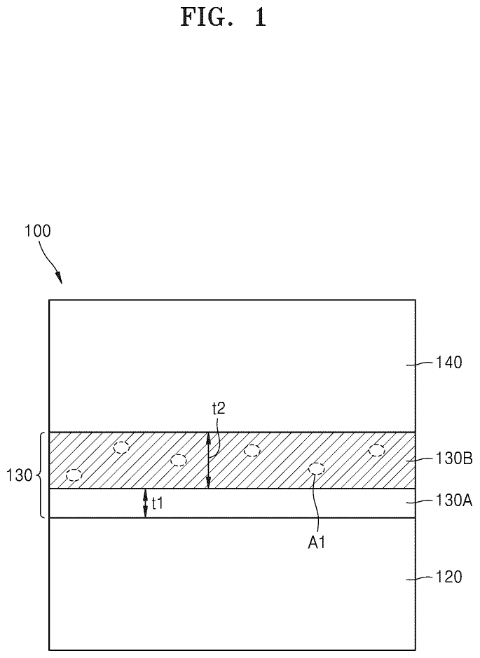

FIG. 1 shows a first capacitor 100 including a nitride-based electrode, according to at least one example embodiment.

Referring to FIG. 1, the first capacitor 100 includes a first electrode layer 120, a first high-k dielectric layer 130, and a second electrode layer 140 that are sequentially stacked. The first electrode layer 120 and the second electrode layer 140 are spaced apart from each other and not in contact with each other. The first high-k dielectric layer 130 may be arranged between the first electrode layer 120 and the second electrode layer 140, may be electrically insulate the first electrode layer 120 from the second electrode layer 140, and may be in direct contact with at least one of the first and/or second electrode layers 120 and 140. The first high-k dielectric layer 130 may be provided to cover at least a part of one surface (e.g., upper surface) of the first electrode layer 120. The second electrode layer 140 may be provided to cover at least a part of one surface (e.g., upper surface) of the first high-k dielectric layer 130. A thickness of the first high-k dielectric layer 130 may be uniform in the entire region of the first high-k dielectric layer 130, but is not limited thereto.

The first electrode layer 120 may be referred to as a lower electrode and the second electrode layer 140 may be referred to as an upper electrode. The first electrode layer 120 may include a nitride-based electrode layer having a relatively high conductivity (e.g., may be a zero-band gap conductor and/or may have a conductive band at the Fermi level). In at least one example embodiment, the nitride-based electrode layer may include a nitride-based material having a relatively high conductivity. In at least one example embodiment, the nitride-based material may be a compound including metal and nitrogen. In at least one example embodiment, the metal in the nitride-based material may include at least one of titanium (Ti), niobium (Nb), vanadium (V), molybdenum (Mo), manganese (Mn), tungsten (W), and/or ruthenium (Ru), and is not limited thereto. In at least one example embodiment, any kind of metal may be used as the metal in the nitride-based material provided that a conductive nitride electrode may be formed. In at least one example embodiment, the first electrode layer 120 may include a TiN electrode layer, but may also include various nitride-based electrode layers in which metal and nitrogen are combined.

The first high-k dielectric layer 130 may be a dielectric layer having a dielectric constant that is greater than that of a silicon oxide (e.g., SiO₂), or may include the dielectric layer. For example, the first high-k dielectric layer 130 may be a dielectric layer having a constant greater than that of silicon oxide, and/or a high-k. For example, the first high-k dielectric layer 130 may be a dielectric layer having a dielectric constant of two, three, four, or more digits (e.g., a dielectric constant of at least one of between 10 or more, 100 or more, 1000 or more, and/or 1000 or more) and/or may include the dielectric layer, but is not limited thereto. Therefore, the first high-k dielectric layer 130 may be expressed as a high dielectric layer or a dielectric layer having high-k, etc. The first high-k dielectric layer 130 may include a single layer, double layers, or multiple layers. In at least one example embodiment, the first high-k dielectric layer 130 may include a first dielectric layer 130A and a second dielectric layer 130B that are sequentially stacked. Dielectric constants (or dielectric rates) of the first dielectric layer 130A and the second dielectric layer 130B may be different from each other. In at least one example embodiment, the first dielectric layer 130A may be a dielectric layer having a dielectric constant less than the second dielectric layer 130B or may include the dielectric layer. The second dielectric layer 130B may be a dielectric layer having a greater dielectric constant than the first dielectric layer 130A or may include the dielectric layer. Therefore, the first dielectric layer 130A may be expressed as a dielectric layer of a lower dielectric constant or low-k, and the second dielectric layer 130B may be expressed as a dielectric layer of a higher dielectric constant or high-k. The first dielectric layer 130A may have a first thickness t1, the second dielectric layer 130B may have a second thickness t2 that is different from the first thickness t1, and are not limited thereto. The first thickness t1 may be less than the second thickness t2, and is not limited thereto. In at least one example embodiment, the first thickness t1 may be 1 nanometers (nm) to 10 nm, 1 nm to 3 nm, or 1 nm to 6 nm, and is not limited thereto. In at least one example embodiment, the second thickness t2 may be 1 nm to 100 nm, 2 nm to 80 nm, 3 nm to 50 nm, or 3 nm to 10 nm, and is not limited thereto. In at least one example embodiment, the first dielectric layer 130A is provided between the second dielectric layer 130B and the first electrode layer 120 and may be classified as an interfacial layer being in direct contact with the first electrode layer 120 and the second dielectric layer 130B. When the first dielectric layer 130A is classified as the interfacial layer, the second dielectric layer 130B may be the first high-k dielectric layer 130. That is, when the first dielectric layer 130A is the interfacial layer, the first high-k dielectric layer 130 may be a single dielectric layer only including the second dielectric layer 130B. In this case, the first capacitor 100 may be considered as a capacitor having a layered structure in which the first electrode layer 120, the interfacial layer 130A, the high-k dielectric layer 130B, and the second electrode layer 140 are sequentially stacked.

During the process of manufacturing the first capacitor 100, the first dielectric layer 130A may be formed as an interfacial layer for protecting against oxidation of the first electrode layer 120. When considering the function of the first dielectric layer 130A, the first dielectric layer 130A may be expressed as an anti-oxidation layer or a protective layer of the first electrode layer 120, or may be expressed as an oxidation-resistant layer having resistivity against the oxidation.

In at least one example embodiment, the first dielectric layer 130A may be a material layer including a binary compound including two different elements. In at least one example embodiment, the first dielectric layer 130A may be a binary oxide layer and/or may include a binary oxide layer. In at least one example embodiment, the binary compound or the binary oxide may be expressed by a chemical formula M₂O_{(3-X)}. In this chemical formula, M may include a material (element) having a reactivity to oxygen, which is greater than that of a metal (e.g., Ti) included in the first electrode layer 120. In at least one example embodiment, M may include yttrium (Y) or scandium (Sc), but is not limited thereto. In the above chemical formula, X may range from 0 to 0.1. In at least one example embodiment, the first dielectric layer 130A may be a Y₂O₃ layer or Sc₂O₃ layer, or may include the above layer.

In at least one example embodiment, the second dielectric layer 130B may be a crystalline dielectric layer, but is not limited thereto. For example, the second dielectric layer 130B may be entirely crystalline, but may also include amorphous regions A1 that are sporadically distributed. In the second dielectric layer 130B, a volume ratio of the amorphous regions A1 may be 20% or less, 15% or less, 10% or less, or 5% or less with respect to the entire second dielectric layer 130B, and is not limited thereto. When the second dielectric layer 130B includes the amorphous regions A1, the amorphous regions A1 are not collected within a restricted region of the second dielectric layer 130B, but may be evenly distributed throughout the entire second dielectric layer 130B. Even when the amorphous regions A1 exist, the ratio of the amorphous regions A1 is very low, and thus, the entire physical status of the second dielectric layer 130B may be considered to be crystalline.

In at least one example embodiment, the second dielectric layer 130B may be a dielectric layer including a ternary compound including three different elements. In at least one example embodiment, the second dielectric layer 130B may include a ternary oxide expressed by a chemical formula ABO₃. In at least one example embodiment, the ternary oxide may include one of SrTiO₃ (STO), BaTiO₃ (BTO), (BaₓSr₁₋ₓ)TiO₃ (BST), SrHfO₃, SrZrO₃, CaTiO₃ (CTO), and/or (CaₓSr₁₋ₓ)TiO₃ (CST). The crystalline structure of the ternary oxide may be the perovskite structure.

In at least one example embodiment, the second electrode layer 140 may include a conductive oxide layer or a metal layer. For example, the second electrode layer 140 may be an electrode layer including RuO₂ as a conductive oxide, but the conductive oxide is not limited to RuO₂. In at least one example embodiment, the metal layer may be a single metal layer. In at least one example embodiment, the metal layer may include an alloy layer.

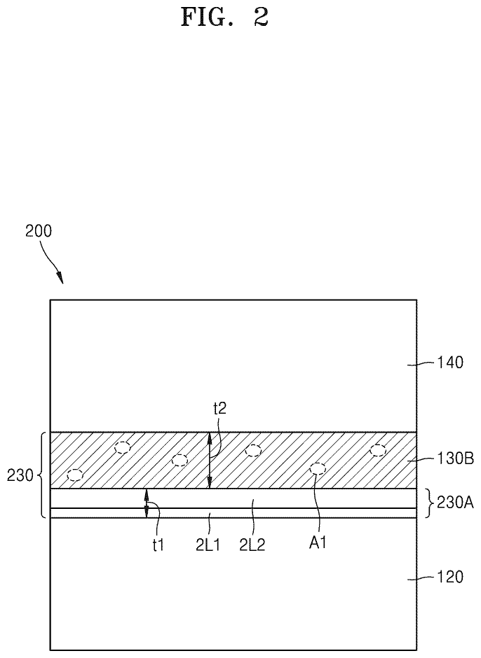

FIG. 2 shows a second capacitor 200 including a nitride-based electrode, according to at least one example embodiment. The second capacitor 200 may be one of modified examples of the first capacitor 100 of FIG. 1. Therefore, differences from the first capacitor 100 are described in the following description about the second capacitor 200. Like reference numerals as those mentioned in the description about the first capacitor 100 denote the same members, and descriptions thereof are omitted. This is equally applied to following descriptions.

Referring to FIG. 2, the second capacitor 200 includes a second high-k dielectric layer 230 between the first electrode layer 120 and the second electrode layer 140. The second high-k dielectric layer 230 includes a third dielectric layer 230A and the second dielectric layer 130B. A position of the third dielectric layer 230A may be the same as the position of the first dielectric layer 130A of the first high-k dielectric layer 130 in the first capacitor 100. Therefore, the second capacitor 200 may correspond to the first capacitor 100 in which the first dielectric layer 130A is replaced with the third dielectric layer 230A. Therefore, a third thickness t3 of the third dielectric layer 230A may be equal to the first thickness t1 of the first dielectric layer 130A, but is not limited thereto.

In at least one example embodiment, a dielectric constant (dielectric ratio) of the third dielectric layer 230A may be less than that of the second dielectric layer 130B, like the first dielectric layer 130A. The third dielectric layer 230A may include a first layer 2L1 and a second layer 2L2 that are sequentially provided. In at least one example, a boundary between the first layer 2L1 and the second layer 2L2 maybe physically indistinct and/or indistinguishable. The first layer 2L1 and the second layer 2L2 may be regions having different physical properties in the same material layer. For example, in at least one example embodiment, the first layer 2L1 may be a layer in which an amount of oxygen is reduced compared to the second layer 2L2. Therefore, the first layer 2L1 may include oxygen vacancies. The first layer 2L1 may have the oxygen vacancies of given concentration. The second layer 2L2 may not include the oxygen vacancy and/or may not substantially include oxygen vacancies. For example, the second layer 2L2 may not include the oxygen vacancies, but an extremely small amount of oxygen vacancies may remain unintentionally in the second layer 2L2 during the process of manufacturing the second capacitor 200. Therefore, even when the oxygen vacancies remain in the second layer 2L2, the amount of the oxygen vacancies may be too small to be ignored as compared with the amount of oxygen vacancies included in the first layer 2L1. Therefore, the second layer 2L2 may be considered as a layer not substantially including the oxygen vacancies. In at least one example embodiment, the first layer 2L1 and the second layer 2L2 may have the same or different thicknesses. For example, the first layer 2L1 may have a thickness less than that of the second layer 2L2, but is not limited thereto.

An ingredient (material) of the third dielectric layer 230A may be the same as that of the first dielectric layer 130A.

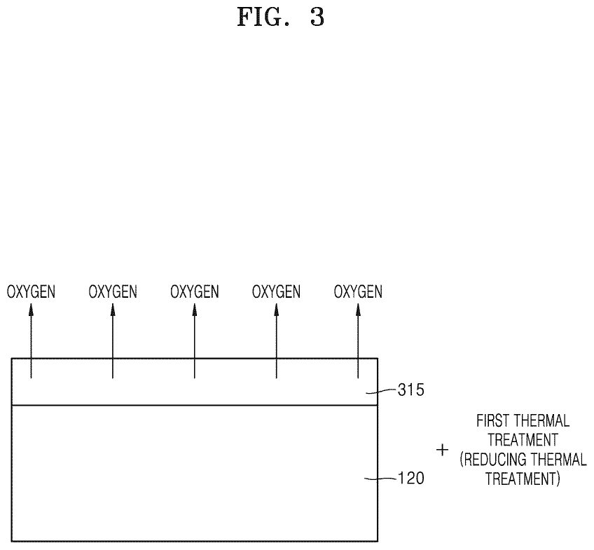

Hereinafter, a method of manufacturing a capacitor including a nitride electrode, according to at least one example embodiment, is described in detail below with reference to FIGS. 3 to 11.

As shown in FIG. 3, a fourth dielectric layer 315 is formed on the first electrode layer 120 as an interfacial layer. The first electrode layer 120 may be formed on a base layer or a lower substrate, but is not shown in FIG. 3. The first electrode layer 120 may be formed by an atomic layer deposition (ALD) method, a chemical vapor deposition (CVD) method, etc., but is not limited thereto. The fourth dielectric layer 315 may be formed as an anti-oxidation layer of the first electrode layer 120. The fourth dielectric layer 315 may be expressed as an oxidation-resistant layer or a protective layer for the first electrode layer 120. The fourth dielectric layer 315 is a binary oxide layer, and may be the dielectric layer that is the same as the first dielectric layer 130A in the first capacitor 100 of FIG. 1. The thickness of the fourth dielectric layer 315 may be equal to the first thickness t1 of the first dielectric layer 130A, but is not limited thereto.

In at least one example embodiment, the fourth dielectric layer 315 may be formed by a pulse laser deposition (PLD) method, but is not limited thereto.

After forming the fourth dielectric layer 315, a reduction process may be performed on the fourth dielectric layer 315. That is, processes for reducing the fourth dielectric layer 315 are performed. In at least one example embodiment, for reducing the fourth dielectric layer 315, a resultant in which the fourth dielectric layer 315 is formed, that is, the first electrode layer 120 and the fourth dielectric layer 315 undergo through a first thermal treatment. The first thermal treatment may be expressed as a thermal treatment for inducing reduction or a thermal treatment for reduction, in consideration of the purpose. In at least one example embodiment, the first thermal treatment may include a forming gas annealing (FGA). Due to the first thermal treatment, some of the oxygen included in the fourth dielectric layer 315 may exit out of the fourth dielectric layer 315. In other words, due to the first thermal treatment, some of the oxygen included in the fourth dielectric layer 315 may be discharged from the fourth dielectric layer 315. In at least one example embodiment, the first thermal treatment may be executed for first time period, under a first gas atmosphere, and at a first temperature. The first thermal treatment may be executed under a first pressure. In at least one example embodiment, the first gas atmosphere may include a gas in which hydrogen (H₂) and an inert gas are mixed or a gas in which hydrogen and nitrogen (N₂) are mixed. In at least one example embodiment, the inert gas may include argon (Ar), but is not limited thereto. A content of the hydrogen gas under the first gas atmosphere may be 5% to 10%, but is not limited thereto. The first temperature may be about 300° C. to about 700° C., but is not limited thereto. The first time period may be 5 minutes to 15 minutes, 8 minutes to 12 minutes, or 10 minutes, but is not limited thereto. The first pressure may be 1 millibar (mbar) to 1 bar.

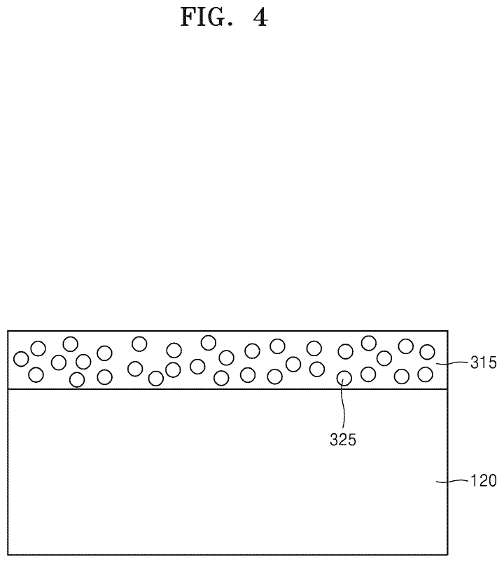

As a result of the first thermal treatment, the fourth dielectric layer 315 may have spaces from which the oxygen is removed, that is, oxygen vacancies 325 as shown in FIG. 4. In a post-process for forming a high-k dielectric layer, the fourth dielectric layer 315 may be exposed to an oxygen atmosphere, and the oxygen may infiltrate into the first electrode layer 120 after passing through the fourth dielectric layer 315 according to the concentration of the oxygen vacancies in the fourth dielectric layer 315. A minimum concentration of the oxygen vacancies 325 in the fourth dielectric layer 315 in order to protect against (e.g., prevent and/or substantially prevent) oxygen from infiltrating into the first electrode layer 120 until the deposition of the high-k dielectric layer is finished, is referred to as a reference concentration. The first thermal treatment may be executed to form the oxygen vacancies 325 of a first concentration in the fourth dielectric layer 315. In at least one example embodiment, the first concentration may be equal to or higher than the reference concentration. When the concentration of the oxygen vacancies 325 in the fourth dielectric layer 315 is greater than the reference concentration, the oxygen vacancies 325 may remain in the fourth dielectric layer 315 even after the deposition of the high-k dielectric layer is finished. When the high-k dielectric layer is deposited, the oxygen vacancies in the upper layer in the fourth dielectric layer 315 may be filled with oxygen. In other words, when the high-k dielectric layer starts to be deposited under the oxygen atmosphere, the fourth dielectric layer 315 may be re-oxidized from the upper layer. Therefore, when the oxygen vacancies 325 remain after the deposition of the high-k dielectric layer is finished, the oxygen vacancies 325 may remain in the lowermost layer of the fourth dielectric layer 315.

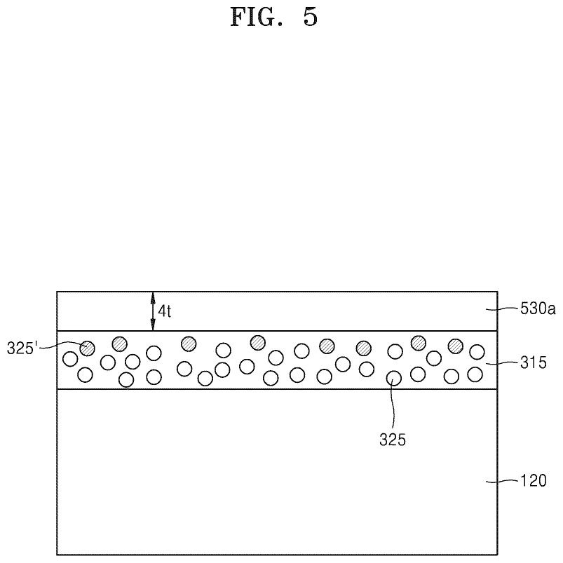

After the first thermal treatment is finished, a fifth dielectric layer 530 of a high-k is formed on the fourth dielectric layer 315 as shown in FIGS. 5 to 7. In at least one example embodiment, the fifth dielectric layer 530 may be the high-k dielectric layer that is the same as the second dielectric layer 130B of the first capacitor 100 in FIG. 1, and may have the second thickness t2 that is equal to that of the second dielectric layer 130B.

FIGS. 5 to 7 show at least one example embodiment of the processes of forming the fifth dielectric layer 530. First, as shown in FIG. 5, a first part 530a of the fifth dielectric layer 530 is formed on the fourth dielectric layer 315. The first part 530a may have a fourth thickness 4t. The fourth thickness 4t is less than the second thickness t2. The first part 530a may be expressed as a first layer or a lower layer of the fifth dielectric layer 530. The first part 530a may be deposited by the ALD or CVD method under a first deposition condition. In at least one example embodiment, the first deposition condition may include a second gas atmosphere, a second temperature, and a second pressure. In at least one example embodiment, the second gas atmosphere may include an oxygen atmosphere including an oxidant such as H₂O₂, H₂O, O₂, or O₃. The second temperature may be 300° C. to 400° C., and is not limited to the above range. The second pressure may be 0.1 mbar to 1 mbar. In at least one example embodiment, the first part 530a may be formed by forming an A layer and a B layer on the fourth dielectric layer 315 by using a precursor including A and a precursor including B of a ternary dielectric substance expressed in a chemical formula ABO₃, and then, oxidizing the A layer and the B layer under the oxygen atmosphere including the oxidant.

While the first part 530a is formed, the fourth dielectric layer 315 may be exposed to the oxygen atmosphere. Accordingly, the oxygen vacancies 325 included in the fourth dielectric layer 315 may be partially filled with oxygen. That is, while the first part 530a is formed, the upper layer of the fourth dielectric layer 315 is oxidized so that the oxygen vacancies 325 may be filled with oxygen. Consequently, when the first part 530a is formed, the oxygen vacancies 325 of the fourth dielectric layer 315 may be reduced. Reference numeral 325′ denote the oxygen vacancy filled with oxygen.

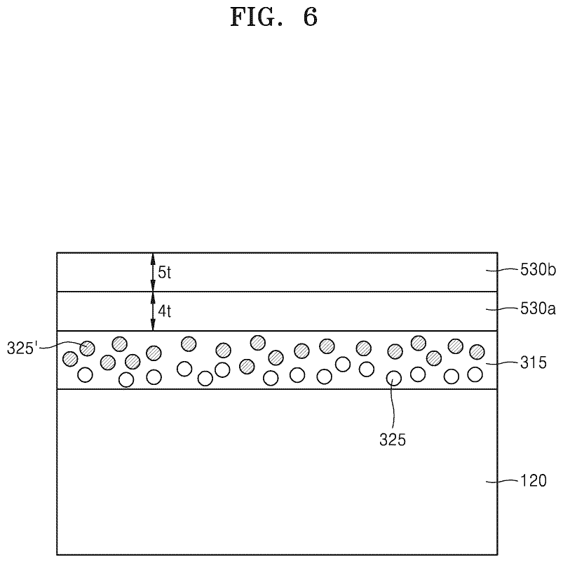

After forming the first part 530a of the fifth dielectric layer 530, as shown in FIG. 6, a second part 530b of the fifth dielectric layer 530 is formed on the first part 530a. The second part 530b may be expressed as a second layer or an intermediate layer of the fifth dielectric layer 530. The second part 530b may have a fifth thickness 5t. The fifth thickness 5t is less than the second thickness t2. The fifth thickness 5t may be equal to or different from the fourth thickness 4t. The second part 530b may be a layer that is successively formed by the same deposition method without changing the deposition condition or stopping the deposition process, after forming the first part 530a. Therefore, the second part 530b may be formed under the first deposition condition. That is, the second part 530b may be formed under the same processing condition as that of the first part 530a. Also, the second part 530b may be the same material layer as the first part.

Like when the first part 530a is formed, the fourth dielectric layer 315 may be under the oxygen atmosphere including the oxidant when the second part 530b is formed. Therefore, the oxygen may be dispersed to the fourth dielectric layer 315 or may infiltrated into the fourth dielectric layer 315. That is, the oxidation of the fourth dielectric layer 315, which starts when the first part 530a is formed, may be continued while the second part 530b is formed. Accordingly, the process of filling the oxygen vacancies 325 with the oxygen in the fourth dielectric layer 315 may be continuously performed. Therefore, after forming the second part 530b, the oxygen vacancies 325 included in the fourth dielectric layer 315 may be less than those before the second part 530b is formed. In other words, the concentration of the oxygen vacancies 325 in the fourth dielectric layer 315 after forming the second part 530b may be less than that before the second part 530b is formed.

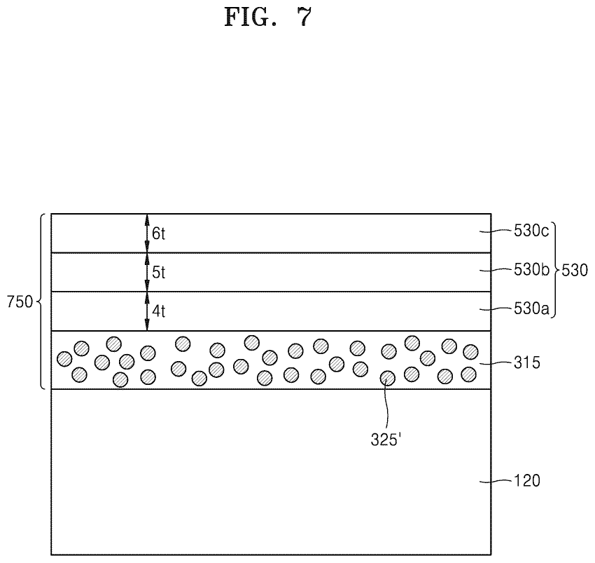

After forming the second part 530b of the fifth dielectric layer 530, as shown in FIG. 7, a third part 530c of the fifth dielectric layer 530 is formed on the second part 530b. The third part 530c may be expressed as a third layer or an upper layer of the fifth dielectric layer 530. The third part 530c may have a sixth thickness 6t. The sixth thickness 6t may be less than the second thickness t2 of the second dielectric layer 130B in the first capacitor 100 of FIG. 1. The sixth thickness 6t may be equal to or different from the fourth thickness 4t or the fifth thickness 5t. Sum (4t+5t+6t) of the fourth to sixth thicknesses 4t, 5t, and 6t may be equal to the second thickness t2 of the second dielectric layer 130B of FIG. 1. The third part 530c may be formed by the same deposition method as that of the first and second parts 530a and 530b. The third part 530c may be a layer that is successively formed by the same deposition method without changing the deposition condition or stopping the deposition process, after forming the second part 530b. Therefore, the third part 530c may be formed under the first deposition condition. That is, the third part 530c may be formed under the same processing condition as that of the first part 530a. Also, the third part 530c may be the same material layer as the first part 530a.

Like when the first part 530a is formed, the fourth dielectric layer 315 may be under the oxygen atmosphere including the oxidant when the third part 530c is formed. Therefore, the oxygen may be dispersed to the fourth dielectric layer 315 or may infiltrated into the fourth dielectric layer 315. That is, the oxidation of the fourth dielectric layer 315, which starts when the first part 530a is formed, may be continued until the third part 530c is formed. Accordingly, the process of filling the oxygen vacancies 325 with the oxygen in the fourth dielectric layer 315 may be continuously performed. In at least one example embodiment, the oxygen vacancies 325 remaining in the fourth dielectric layer 315 after forming the second part 530b may be filled with oxygen while the third part 530c is formed. Consequently, the oxygen vacancies in the fourth dielectric layer 315 may disappear and/or may be substantially considered as having been disappeared while the third part 530c is formed. Here, the term “substantially considered as having been disappeared” may denote a condition in which the oxygen vacancies of low concentration and/or small number that may not be included within a measurement range and/or is within a tolerance thereof may remain in the fourth dielectric layer 315, whereas the oxygen vacancies may be completely disappeared from the fourth dielectric layer 315, according to a fine variation in the deposition condition of the third part 530c, and in this case, it may be considered that the oxygen vacancies are completely disappeared from the fourth dielectric layer 315.

When the deposition of the third part 530c is finished, the deposition process of the fifth dielectric layer 530 on the fourth dielectric layer 315 is finished. When the fifth dielectric layer 530 that is the high-k dielectric layer is deposited on the fourth dielectric layer 315 that is an interfacial layer, a third high-k dielectric layer 750 is deposited on the first electrode layer 120. The third high-k dielectric layer 750 is in a state before a crystallization process is performed, and after performing the crystallization process, the third high-k dielectric layer 750 may correspond to the first high-k dielectric layer 130 in the first capacitor 100 of FIG. 1.

In at least one example embodiment, the third high-k dielectric layer 750 may not include the third part 530c of the fifth dielectric layer 530. In other words, the deposition process of the fifth dielectric layer 530 may be finished with the process of depositing the first and second parts 530a and 530b. That is, the deposition process of the fifth dielectric layer 530 may be finished at the process of depositing the second part 530b illustrated in FIG. 6. In this case, the oxygen vacancies 325 may remain in the lower layer part of the fourth dielectric layer 315 as shown in FIG. 6. Consequently, the third high-k dielectric layer 750 may have a layered structure including the fourth dielectric layer 315 that includes the oxygen vacancies 325 in the lower layer part and the fifth dielectric layer 530 that includes the first and second parts 530a and 530b. When the third high-k dielectric layer 750 having the above layered structure undergoes through the crystallization process, the third high-k dielectric layer 750 may correspond to the second high-k dielectric layer 230 in the second capacitor 200 of FIG. 2. In addition, in the layered structure, sum (4t+5t) of the fourth thickness 4t and the fifth thickness 5t of the first and second parts 530a and 530b in FIG. 6 may be equal to the second thickness t2 of the second dielectric layer 130B in the second capacitor 200 of FIG. 2.

For convenience of description, the processes of depositing the fifth dielectric layer 530 are described after dividing into the first to third parts 530a, 530b, and 530c, but the entire deposition process of the fifth dielectric layer 530 may be continuously executed without stopping from the start to the end under the first deposition condition.

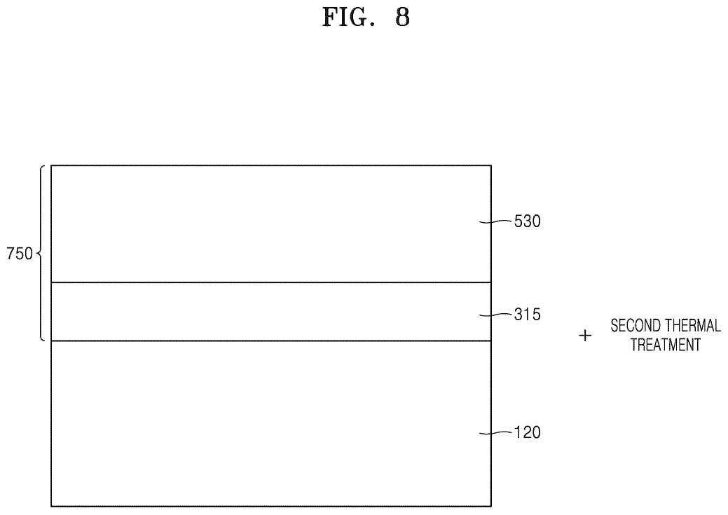

Therefore, the fifth dielectric layer 530 may be represented as one layer without distinguishing layers, as shown in FIG. 8. Based on FIG. 7, after finishing the deposition process of the fifth dielectric layer 530, the oxygen vacancies are disappeared from the fourth dielectric layer 315, and this denotes that the fourth dielectric layer 315 becomes to the state before reduction. Therefore, the fourth dielectric layer 315 is also represented without any sign of the oxygen vacancies, as shown in FIG. 8.

After finishing the deposition process of the fifth dielectric layer 530, as shown in FIG. 8, a second thermal treatment is performed on the resultant in which the fifth dielectric layer 530 is deposited, that is, the second electrode layer 120, the fourth dielectric layer 315 that is the interfacial layer, and the fifth dielectric layer 530. The second thermal treatment may be a thermal treatment for crystallization of the fifth dielectric layer 530 in the amorphous state. In at least one example embodiment, the second thermal treatment may be executed by using a rapid thermal annealing (RTA), but is not limited thereto. In at least one example embodiment, the second thermal treatment may be executed at a temperature of 500° C. to 700° C., but is not limited thereto.

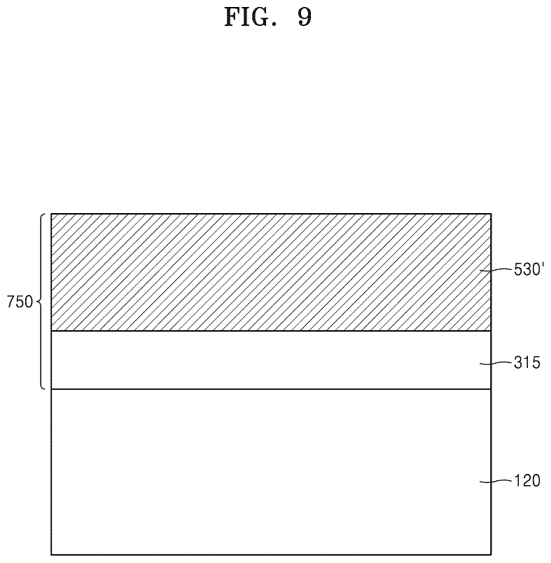

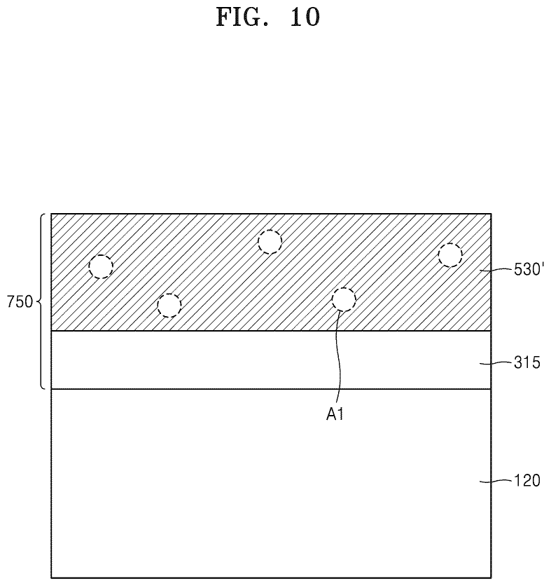

As a result of the second thermal treatment, the fifth dielectric layer 530 may be in an entirely crystalline state, and as shown in FIG. 9, the fifth dielectric layer 530′ that is crystallized is formed on the fourth dielectric layer 315.

In at least one example embodiment, the crystallization may completely occur throughout the entire fifth dielectric layer 530 according to the second thermal treatment, but very fine regions in the fifth dielectric layer 530 may remain as the amorphous regions. Therefore, in the example, the crystallized fifth dielectric layer 530′ may include amorphous regions A1 that are sporadically distributed as shown in FIG. 10. In the crystallized fifth dielectric layer 530′, a ratio of the amorphous regions A1 may be the same as the description with reference to FIG. 1.

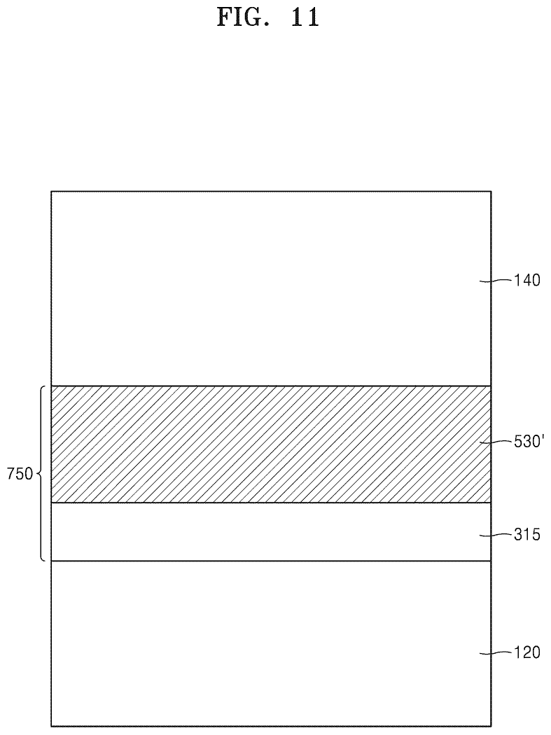

After forming the crystallized fifth dielectric layer 530′, as shown in FIG. 11, the second electrode layer 140 is formed on the crystallized fifth dielectric layer 530′. Through the above processes, the capacitor may be formed.

Next, experiments executed in relation to manufacturing of the capacitor according to at least one example embodiment, and results therefrom are described.

Through the above experiments, it was identified that the interfacial film (anti-oxidation film), e.g., the fourth dielectric layer 315, used in the above method of manufacturing the capacitor had the reduction property, and before and after the reduction, it was identified whether there is a variation in the thickness of the fourth dielectric layer 315. Also, through the above experiments, TiN electrode anti-oxidation effects and capacitance were compared among a capacitor manufacturing without an interfacial film, a capacitor manufactured by using the interfacial film that is not reduced, and a capacitor manufactured by using the reduced interfacial film, that is, the fourth dielectric layer 315 having the oxygen vacancies 325 (e.g., the first capacitor 100 of FIG. 1).

The above experiments may be classified as a first experiment and a second experiment according to a material used as the interfacial film. In the first experiment, a Y₂O₃ film was used as the interfacial film, and in the second experiment, a Sc₂O₃ film was used as the interfacial film.

### 1) First Experiment and Result

First, in order to check whether the Y₂O₃ film used as the interfacial film has a reduction condition, the Y₂O₃ film was deposited on the TiN electrode layer, and after that, the Y₂O₃ film was thermally treated for a given time under a gas atmosphere including hydrogen and nitrogen. The TiN electrode layer was formed to a thickness of 10 nm by using the ALD method, and the Y₂O₃ film was formed to a thickness of 1 nm to 2 nm by using the PLD method. In addition, the gas atmosphere was prepared by mixing 5% of H₂ and 95% of N₂. The above thermal treatment was for reduction and was performed for 10 minutes at the temperature of 300° C. to 700° C. by the FGA method.

After forming the Y₂O₃ film, an X-ray photoelectron spectroscopy (XPS) was used to analyze the Y₂O₃ film.

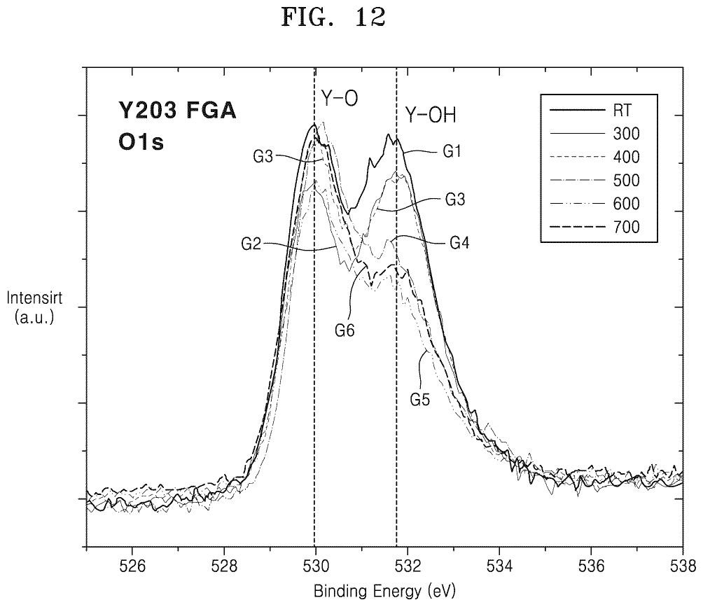

FIG. 12 shows an XPS analysis result for the Y₂O₃ film. In FIG. 12, a horizontal axis denotes a binding energy and a longitudinal axis denotes an intensity of electrons that are emitted.

In FIG. 12, first to sixth graphs G1 to G6 denote results when the thermal treatment temperature was room temperature, 300° C., 400° C., 500° C., 600° C., and 700° C., respectively.

When comparing the first to sixth graphs G1 to G6, a relative intensity of Y-OH peak greatly reduces at the temperature of 500° C. or greater, and this suggests that the Y ₂O₃ film is reduced at the temperature of 500° C. or greater.

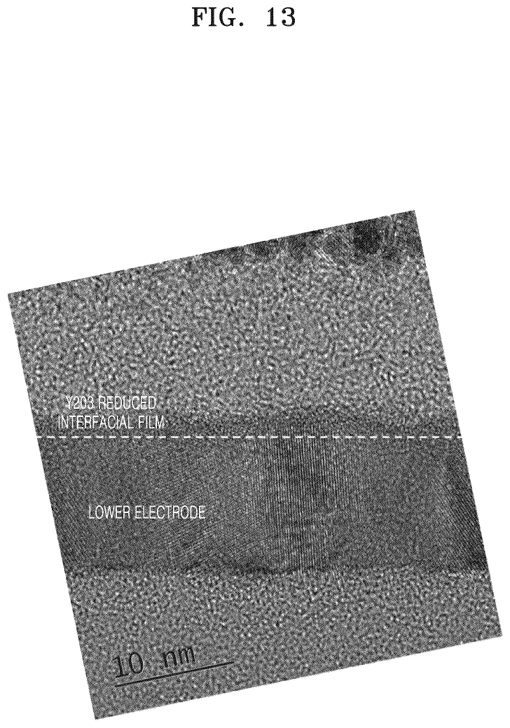

FIG. 13 shows a transmission electron microscope (TEM) photograph of the Y₂O₃ film that is thermally treated at the temperature of 600° C.

Referring to FIG. 13, an interface between the TiN lower electrode and the Y₂O₃ film is maintained. This suggests that the interface of the Y₂O₃ film is maintained constantly before and after reduction.

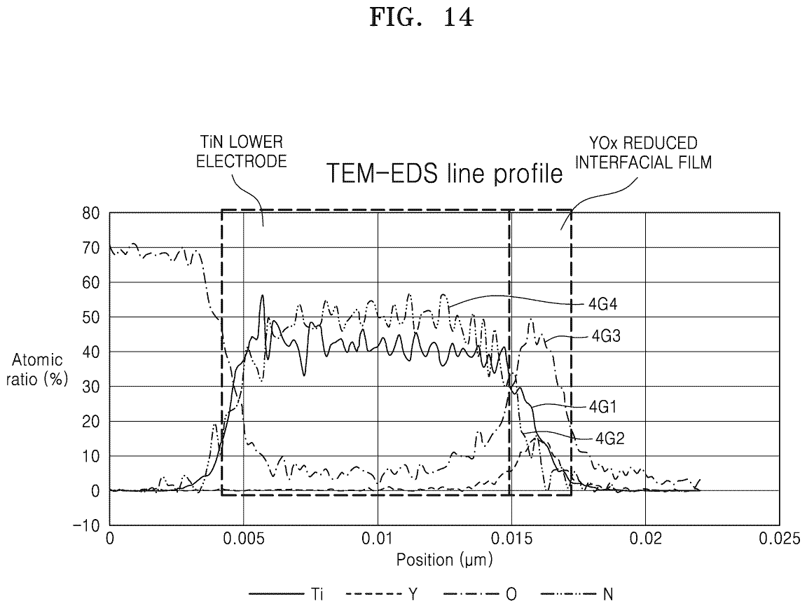

FIG. 14 shows a TEM-EDS analysis result executed to check the composition distribution of a TiN electrode and the Y₂O₃ film thermally treated at the temperature of 600° C. In FIG. 14, first to fourth graphs 4G1 to 4G4 respectively denote titanium distribution, yttrium distribution, oxygen distribution, and nitrogen distribution.

Referring to the first to fourth graphs 4G1 to 4G4, the interface between the TiN electrode and the Y₂O₃ film is maintained without inter-diffusion therebetween.

The results of FIGS. 13 and 14 denote that, even after the thermal treatment for inducing reduction on the Y₂O₃ film, the composition, thickness, and the interface of the TiN electrode and the Y₂O₃ film are maintained equal to or substantially equal to those before the thermal treatment for inducing reduction.

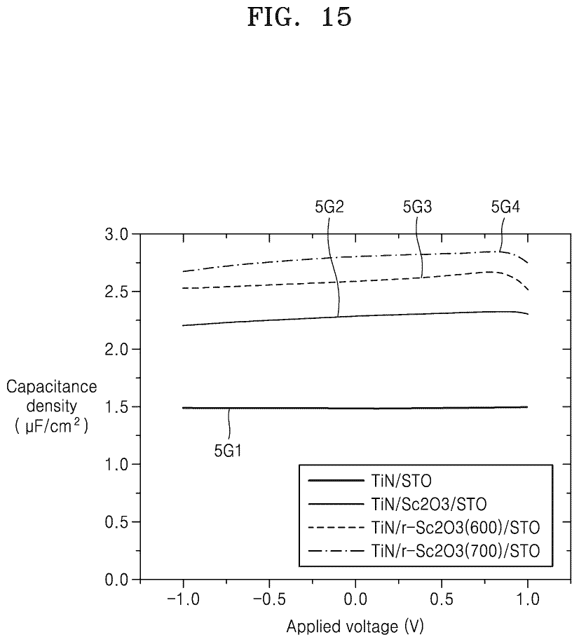

FIG. 15 shows a capacitance measured with respect to a capacitor of an MIM type, which uses the TiN electrode as a lower electrode, an STO film as the dielectric substance, and an RuO₂ electrode as the upper electrode.

The STO film was deposited on the TiN electrode by the ALD method, and then, an RTA was performed for about 2 minutes at the temperature of 650° C. for crystallizing the STO film.

In FIG. 15, a first graph 5G1 is about a first sample capacitor in which the TiN electrode, an STO film, and the RuO₂ electrode are sequentially stacked. The first sample capacitor does not have an interfacial film between the TiN electrode and the STO film.

A second graph 5G2 is about a second sample capacitor in which the TiN electrode, an interfacial film (nr-Y₂O₃ film), the STO film, and the RuOₓ electrode are sequentially stacked. “nr-Y₂O₃ film” denotes the Y₂O₃ film that is not reduced, that is, does not undergo through the thermal treatment for reduction.

A third graph 5G3 is about a third sample capacitor in which the TiN electrode, the interfacial film (r-Y₂O₃ film 600), the STO film, and the RuO₂ electrode are sequentially stacked. “r-Y₂O₃ film 600” denotes the Y₂O₃ film that is thermally treated at the temperature of 600° C. for reduction. The third sample capacitor may correspond to the capacitor according to the above embodiment.

A fourth graph 5G4 is about a fourth sample capacitor in which the TiN electrode, the interfacial film (r-Y₂O₃ film 700), the STO film, and the RuO₂ electrode are sequentially stacked. “r-Y₂O₃ film 700” denotes the Y₂O₃ film that is thermally treated at the temperature of 700° C. for reduction. The fourth sample capacitor may correspond to the capacitor according to the above embodiment.

The third and fourth sample capacitors may be a comparison group, and the first and second sample capacitors may be a control group for the comparison group.

When comparing the first to fourth graphs 5G1 to 5G4, in the first sample capacitor (comparison group 1), a capacitance density is about 1.5 μF/cm², and a capacitance density of the second sample capacitor (comparison group 2) is greater than that of the first sample capacitor but less than those of the third and fourth sample capacitors. The low capacitance density of the first sample capacitor is because a low-k dielectric film (TiNₓO_{y}, TiO₂) is formed between the TiN electrode and the STO film due to the oxidation of the TiN electrode during the process of the STO film because there is no interfacial film.

Even when the second to fourth sample capacitors all use the Y₂O₃ film as the interfacial layer, the capacitance densities of the third and fourth sample capacitors are greater than that of the second sample capacitor. Without being limited to a specific theory, this result is at least caused by whether the TiN electrode is oxidized or not according to whether the thermal treatment for inducing reduction is performed on the Y₂O₃ film.

Consequently, the result of FIG. 15 teaches that oxidation of the TiN electrode during the process of forming the STO film may not be protected against only by forming the interfacial film between the TiN electrode and the STO film, and that the oxidation of the TiN electrode may be protected against when the STO film is formed after performing the thermal treatment for inducing reduction on the interfacial layer.

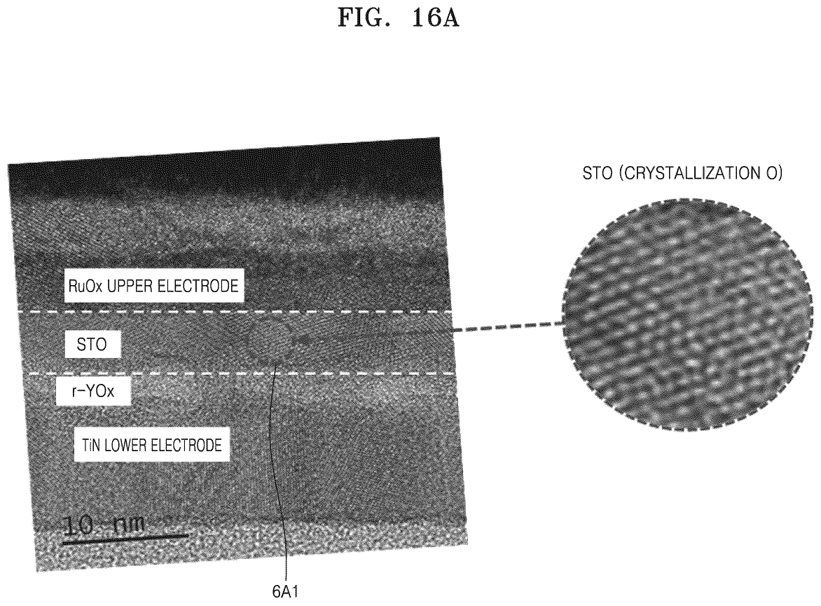

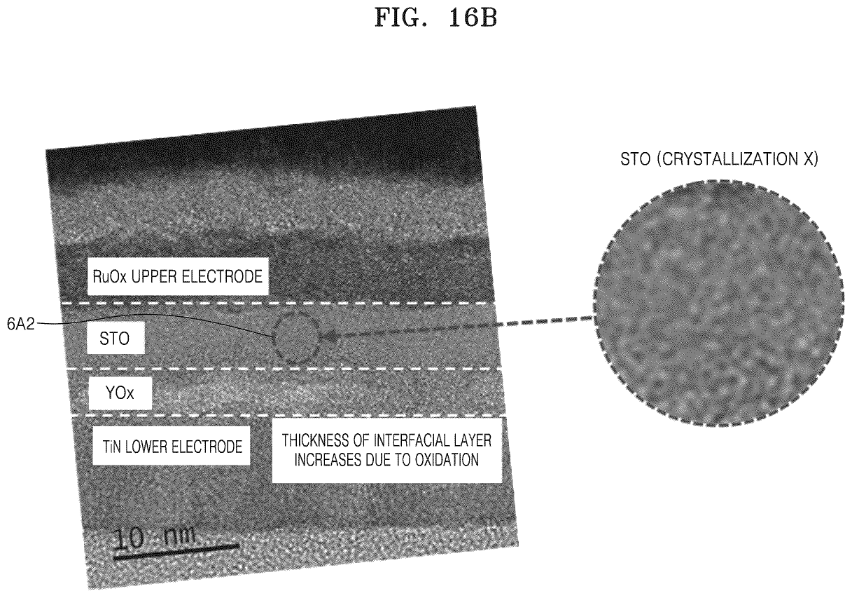

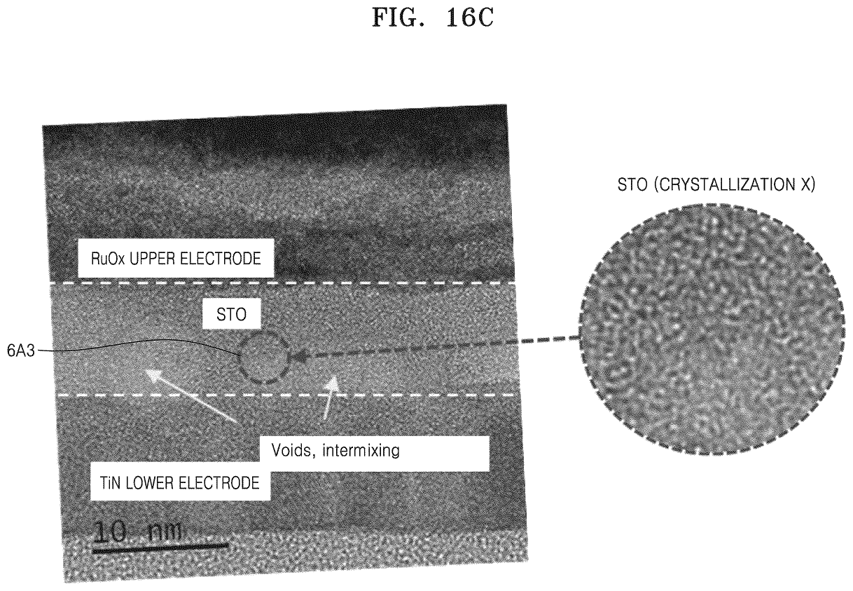

FIG. 16A, FIG. 16B, and FIG. 16C show TEM pictures of the first sample capacitor and the second and third sample capacitors in which the Y₂O₃ film, that is, the interfacial film, is formed to a thickness of 20 Å. The layered structure and materials in the fourth sample capacitor are the same as those of the third sample capacitor, and thus, the TEM picture of the fourth sample capacitor is omitted.

In FIG. 16A, “r-YOx” denotes the Y₂O₃ film that has undergone through the thermal treatment for inducing reduction, and “YOx” of FIG. 16B denotes the Y₂O₃ film that does not undergo through the thermal treatment for inducing reduction.

FIG. 16A is about the third sample capacitor, and shows that the initial thickness, 20 Å, of the Y₂O₃ film is maintained. In FIG. 16A, a circle at the right of the picture is a magnified view of a first region 6A1 of the STO film, and shows that the STO film is crystallized. The above result in FIG. 16A shows that the oxidation of the TiN layer may be protected against due to the Y₂O₃ film during the process of forming the third sample capacitor, and denotes that the capacitance density of the third sample capacitor may be greater than those of the first and second sample capacitors.

FIG. 16B is about the second sample capacitor, and shows that the Y₂O₃ film has a thickness greater than that of the Y₂O₃ film in FIG. 16A. A part of the TiN electrode is oxidized during the process of forming the STO film. In FIG. 16B, a circle at the right side of the picture shows a magnified view of a second region 6A2 in the STO film corresponding to the first region 6A1 in FIG. 16A, and does not show the crystallized state unlike from FIG. 16A. This suggests that the STO film in the second sample capacitor is mostly amorphous region. Due to the above result, the capacitance density of the second sample capacitor may be inevitably less than those of the third and fourth sample capacitors.

FIG. 16C is about the first sample capacitor having no interfacial layer. FIG. 16C shows that a lot of voids are formed in the interface between the TiN electrode and the STO film, and that a composition changes in the lower layer of the STO film, due to the oxidation of the TiN electrode and inter diffusion between the TiN electrode and the STO film in the process of forming the STO film. In FIG. 16C, a circle at the right side of the picture shows a magnified view of a third region 6A3 in the STO film, and like in FIG. 16B, the crystallized state is not shown. This suggests that the STO film of the first sample capacitor is mostly in the amorphous state. The above result illustrates the reason why the capacitance density of the first sample capacitor is less than that of the second sample capacitor.

### 2) Second Experiment and Result

In the second experiment, instead of the Y₂O₃ film, an Sc₂O₃ film is used as the interfacial film, and the other experimental members, preparing processes, and experiment condition are the same as those of the first experiment.

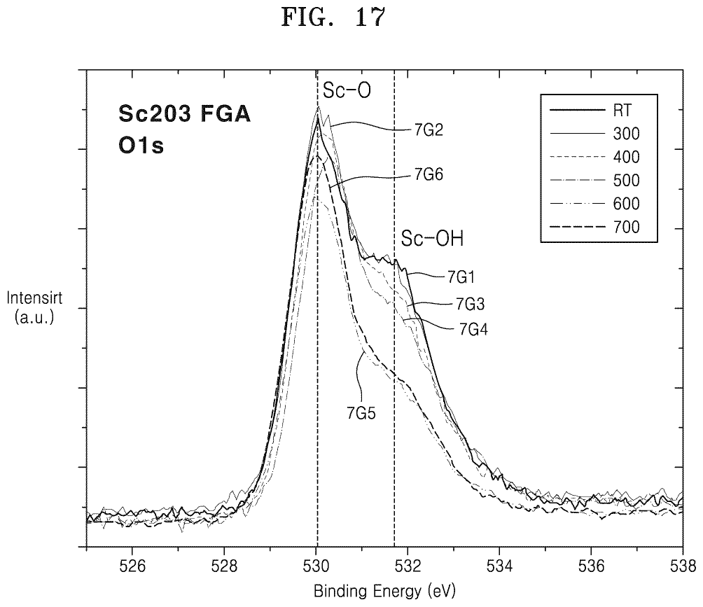

FIG. 17 shows an XPS analysis result for the Sc₂O₃ film. In FIG. 17, a horizontal axis denotes a binding energy and a longitudinal axis denotes an intensity of electrons that are emitted.

In FIG. 17, first to sixth graphs 7G1 to 7G6 show results when the thermal treatment temperature for reducing the Sc₂O₃ film is a room temperature, 300° C., 400° C., 500° C., 600° C., and 700° C., respectively.

When comparing the first to sixth graphs 7G1 to 7G6, a relative intensity of Sc-OH peak greatly reduces at the temperature of 500° C. or greater, and this denotes that the Sc ₂O₃ film is reduced at the temperature of 500° C. or greater.

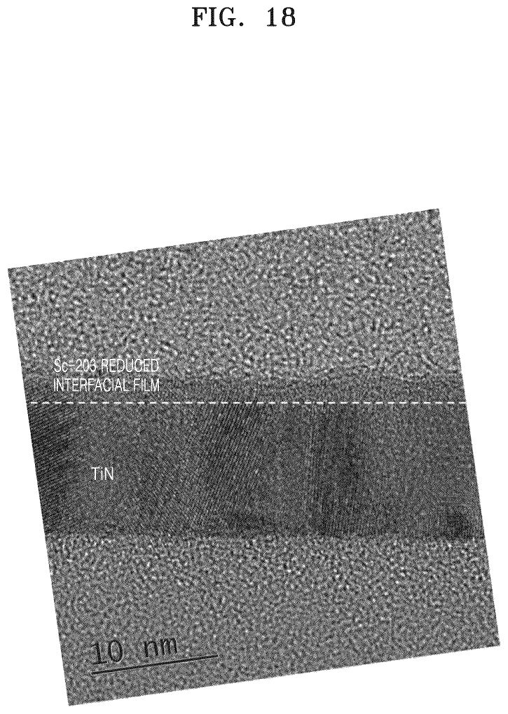

FIG. 18 shows a TEM photograph of the Sc₂O₃ film that is thermally treated at the temperature of 600° C.

Referring to FIG. 18, the interface between the TiN lower electrode and the Sc₂O₃ film is stably maintained, and this suggests that the interface of the Sc₂O₃ film is maintained constantly before and after the reduction.

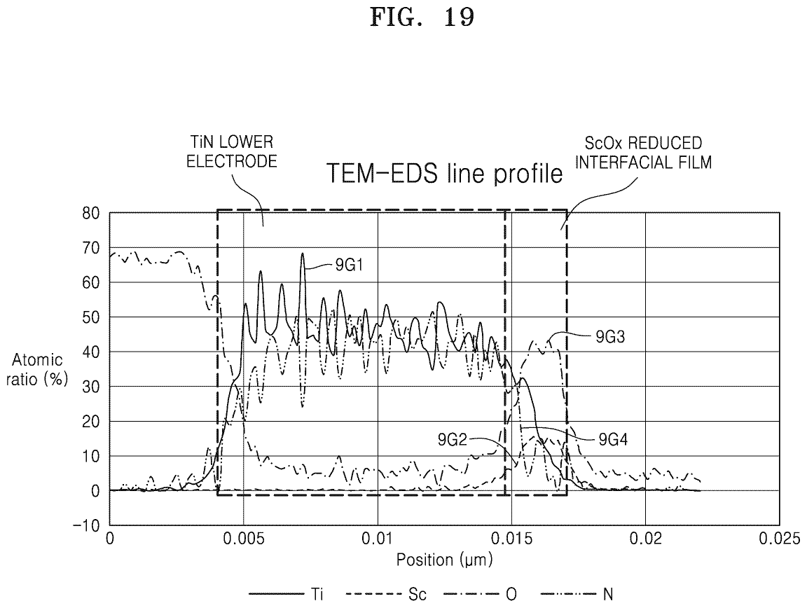

FIG. 19 shows a TEM-EDS analysis result executed to check the composition distribution of a TiN electrode and the Sc₂O₃ film thermally treated at the temperature of 600° C. In FIG. 19, first to fourth graphs 9G1 to 9G4 respectively denote titanium (Ti) distribution, scandium (Sc) distribution, oxygen (O) distribution, and nitrogen (N) distribution in the TiN electrode and the Sc₂O₃ film.

Referring to the first to fourth graphs 9G1 to 9G4, the interface between the TiN electrode and the Sc₂O₃ film is maintained without inter-diffusion between the TiN electrode and the Sc₂O₃ film.

The results of FIGS. 18 and 19 denote that, even after the thermal treatment for inducing reduction on the Sc₂O₃ film, the composition, thickness, and the interface of the TiN electrode and the Sc₂O₃ film are maintained equal to or substantially equal to those before the thermal treatment for inducing reduction.

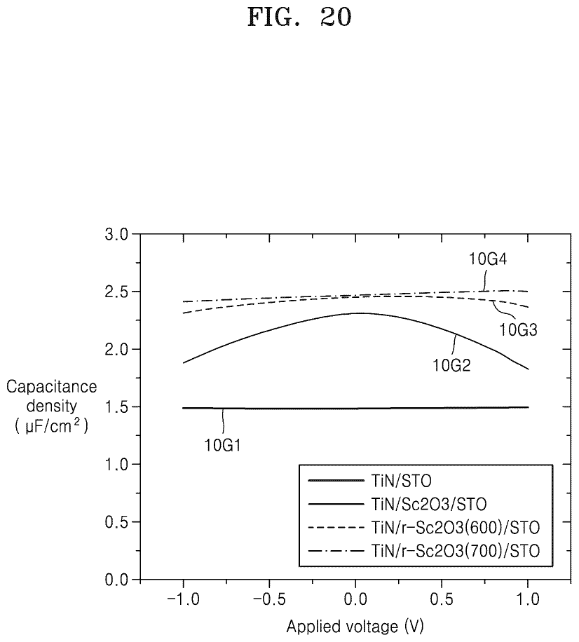

FIG. 20 shows a capacitance measured with respect to a capacitor of an MIM type, which uses the TiN electrode as a lower electrode, an STO film as the dielectric substance, and an RuO₂ electrode as the upper electrode.

In FIG. 20, a first graph 10G1 is about a fifth sample capacitor in which the TiN electrode, the STO film, and the RuO₂ electrode are sequentially stacked. The fifth sample capacitor does not have an interfacial film between the TiN electrode and the STO film.

A second graph 10G2 is about a sixth sample capacitor in which the TiN electrode, an interfacial layer (nr-Sc₂O₃ film), the STO film, and the RuO₂ electrode are sequentially stacked. “nr-Sc₂O₃ film ” denotes a Sc₂O₃ film that does not undergo through the thermal treatment for reducing reduction.

A third graph 10G3 is about a seventh sample capacitor in which the TiN electrode, the interfacial layer (r-Sc₂O₃ film 600), the STO film, and the RuO₂ electrode are sequentially stacked. “r-Sc₂O₃ film 600” denotes the Sc₂O₃ film that is thermally treated at the temperature of 600° C. for reduction. The seventh sample capacitor may correspond to the capacitor according to the above embodiment.

A fourth graph 10G4 is about an eighth sample capacitor in which the TiN electrode, the interfacial film (r-Sc₂O₃ film 700), the STO film, and the RuO Sc₂O₃ electrode are sequentially stacked. “r-Sc₂O₃ film 700” denotes the Sc₂O₃ film that is thermally treated at the temperature of 700° C. for reduction. The eighth sample capacitor may correspond to the capacitor according to the above embodiment.

The seventh and eighth sample capacitors may be a comparison group, and the fifth and sixth sample capacitors may be a control group for the comparison group.

When comparing the first to fourth graphs 10G1 to 10G4, in the fifth sample capacitor (comparison group 3), a capacitance density is about 1.5 μF/cm², and a capacitance density of the sixth sample capacitor (comparison group 4) is greater than that of the fifth sample capacitor but less than those of the seventh and eighth sample capacitors. The low capacitance density of the fifth sample capacitor may be because a low-k dielectric film (TiNₓO_{y}, TiO₂) is formed between the TiN electrode and the STO film due to the oxidation of the TiN electrode during the process of the STO film because there is no interfacial layer.

Even when the sixth to eighth sample capacitors all use the Sc₂O₃ film as the interfacial layer, the capacitance densities of the seventh and eighth sample capacitors are greater than that of the sixth sample capacitor. Without being limited to a specific theory, this result is at least caused by whether the TiN electrode is oxidized or not according to whether the thermal treatment for inducing reduction is performed on the Sc₂O₃ film.

Consequently, the result of FIG. 20 suggests that, even when the Sc₂O₃ interfacial film is formed between the TiN electrode and the STO film, the oxidation of the TiN electrode may not be protected against during the process of forming the STO film, but may be protected against by forming the STO film after performing the thermal treatment for inducing reduction on the interfacial film.

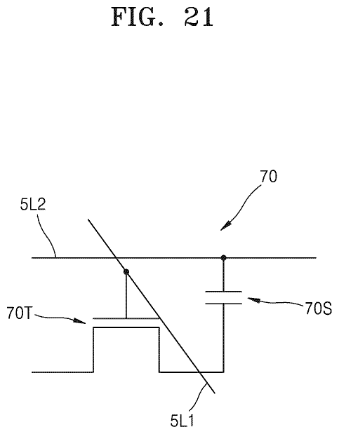

FIG. 21 shows a semiconductor device 70 according to at least one example embodiment. The semiconductor device 70 may be a memory device provided at a cross point between a first wiring 5L1 and a second wiring 5L2. The semiconductor device 70 may correspond to a unit memory or a memory cell, for example, may be a unit memory cell of a volatile memory device (e.g., DRAM).

Referring to FIG. 21, the semiconductor device 70 may include a field effect transistor (FET) 70T that is one of switching elements and one data storage element 70S connected to the field effect transistor 70T.

In at least one example embodiment, the data storage element 70S may include a volatile or non-volatile data storage element. In at least one example embodiment, the data storage element 70S may include the first capacitor 100 or the second capacitor 200 described above. A gate of the field effect transistor 70T may be connected to the first wiring 5L1, a first side of the data storage element 70S may be connected to the field effect transistor 70T, and a second side opposite to the first side may be connected to the second wiring 5L2. One of the first wiring 5L1 and the second wiring 5L2 may be a word line and the other may be a bit line.

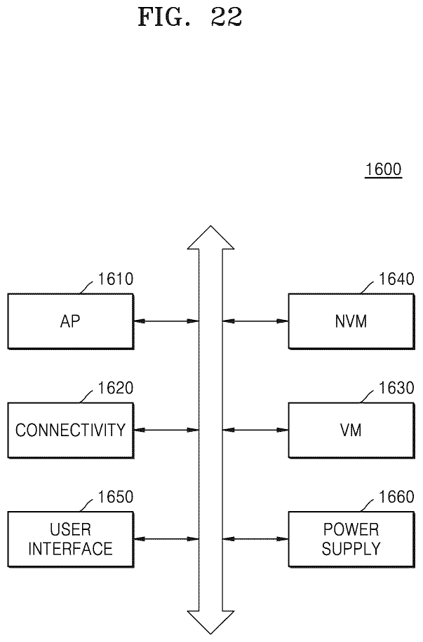

FIG. 22 is a block diagram of an electronic system according to at least one example embodiment.

Referring to FIG. 22, an electronic system 1600 may include an application processor (AP) 1610, a connectivity unit 1620, a volatile memory device (VM) 1630, a non-volatile memory device (NVM) 1640, a user interface 1650, and a power supply 1660. For example, the electronic system 1600 may be a mobile system or may include a mobile system.

The AP 1610 may execute applications for providing Internet browser, games, videos, etc. The connectivity unit 1620 may perform wireless communication or wired communication with an external device.

The VM 1630 may store data processed by the AP 1610 or may act as a working memory. The NVM 1640 may include a boot image for booting the electronic system 1600. The user interface 1650 may include one or more input devices such as a keypad or a touch screen, and/or one or more output devices such as a speaker or a display apparatus. The power supply 1660 may supply a working voltage to the electronic system 1600. Also, according to embodiments, the electronic system 1600 may further include a camera image processor (CIP), and a storage device such as a memory card, a solid state drive (SSD), a hard disk drive (HDD), a CD-ROM, etc.

In at least one example embodiment, the NVM 1640 may include one of the first and second capacitors 100 and 200 shown in FIGS. 1 and 2, or may include the semiconductor device 70 shown in FIG. 21.

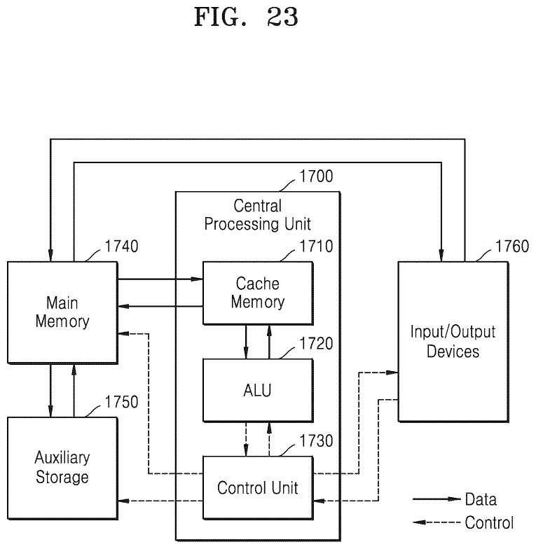

FIG. 23 is a conceptual diagram schematically showing device architectures applied to an electronic apparatus, according to at least one example embodiment.

Referring to FIG. 23, a central processor unit (CPU) 1700 may include a cache memory 1710, an arithmetic logic unit (ALU) 1720, and a control unit 1730, and the cache memory 1710 may include a static random access memory (SRAM). Separately from the CPU 1700, a main memory 1740 and an auxiliary storage 1750 may be provided. The main memory 1740 may include a DRAM device. In at least one example embodiment, the DRAM device may include one of the first and second capacitors 100 and 200 shown in FIGS. 1 and 2. In at least one example embodiment, the DRAM device may include the semiconductor device 70 of FIG. 21 as a unit memory cell.

A device architecture may be implemented in a form in which computing unit devices and memory unit devices are adjacent to each other in one chip, without distinction of sub-units.

In FIG. 23, reference numeral 1760 denotes a device for data input/output.

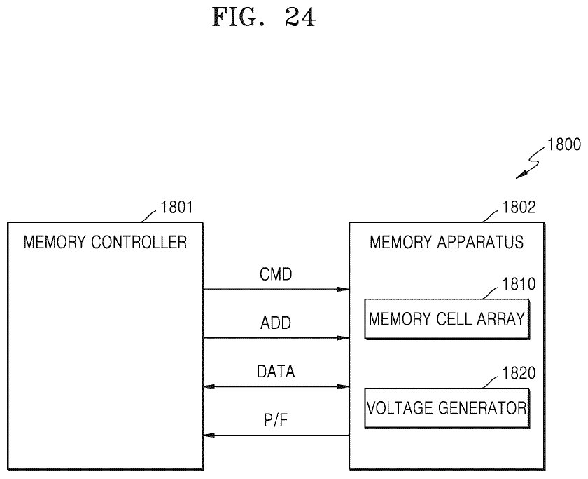

FIG. 24 is a block diagram of a memory system 1800 according to at least one example embodiment.

Referring to FIG. 24, the memory system 1800 may include a memory controller 1801 and a memory device 1802. The memory controller 1801 may perform control operations on the memory device 1802. For example, the memory controller 1801 provides the memory device 1802 with an address ADD and a command CMD for performing programming (or recording), reading, and/or erasing operations on the memory device 1802. Also, data for the programming operation and read data may be transferred between the memory controller 1801 and the memory device 1802.

The memory device 1802 may include a memory cell array 1810 and a voltage generator 1820. The memory cell array 1810 may include a plurality of memory cells, and each of the memory cells may include one of the first and second capacitors 100 and 200 shown in FIGS. 1 and 2 and/or the semiconductor device 70 shown in FIG. 21.

The memory controller 1801 may include a processing circuit such as hardware including a logic circuit, a combination of hardware/software such as processor executed software, or a combination thereof. For example, the processing circuit may include, in particular, a central processing unit (CPU), an arithmetic logic unit (ALU), a digital signal processor, a micro-computer, a field programmable gate array (FPGA), a system-on-chip (SoC), a programmable logic unit, a micro-processor, an application-specific integrated circuit (ASIC), etc., but is not limited thereto. The memory controller 1801 may operate in response to a request from a host (not shown) and may access the memory device 1802 to control the control operation (e.g., writing/reading operation) discussed as above, and thus, the memory controller 1801 may be converted into a special purpose controller. The memory controller 1801 may generate an address ADD and a command CMD for performing programming/reading/erasing operations on the memory cell array 1810. Also, in response to the command from the memory controller 1801, the voltage generator 1820 (e.g., power circuit) may generate a voltage control signal for controlling a voltage level of a word line in order to perform data programming or data reading on the memory cell array 1810.

Also, the memory controller 1801 may perform a determination operation with respect to the data read from the memory device 1802. For example, from the data read from the memory cell, the number of on-cells and/or the number of off-cells may be determined. The memory device 1802 may provide the memory controller 1801 with a pass/fail signal (P/F) according to the determination result with respect to the read data. The memory controller 1801 may control the writing/reading operation of the memory cell array 1810 with reference to the pass/fail signal (P/F).

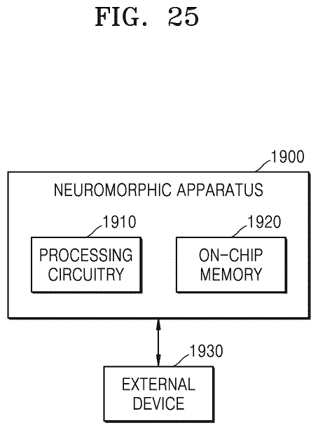

FIG. 25 is a block diagram showing a neuromorphic device 1900 and an external device connected to the neuromorphic device according to at least one example embodiment.

Referring to FIG. 25, the neuromorphic device 1900 may include a processing circuit 1910 and/or an on-chip memory 1920. The neuromorphic device 1900 may include one of the first and second capacitors 100 and 200 shown in FIGS. 1 and 2, or may include the semiconductor device 70 shown in FIG. 21.

In some example embodiments, the processing circuit 1910 may be configured to control functions for driving the neuromorphic device 1900. For example, the processing circuit 1910 may be configured to control the neuromorphic device 1900 by executing a program stored in the on-chip memory 1920. In some embodiments, the processing circuit 1910 may include hardware such as a logic circuit, hardware/software combination such as a processor executing software, or a combination thereof. For example, the processor may include, but is not limited to, a CPU, a graphic processing unit (GPU), an application processor (AP) included in the neuromorphic device 1900, an ALU, a digital signal processor, a micro-computer, a FPGA, an SoC, a programmable logic unit, a micro-processor, an ASIC, etc. In some embodiments, the processing circuit 1910 may be configured to read/write various data with respect to an external device 1930 and/or to execute the neuromorphic device 1900 by using the read/written data. In some embodiments, the external device 1930 may include an external memory and/or sensor array having an image sensor (e.g., CMOS image sensor circuit).

In at least one example embodiment, the neuromorphic device 1900 of FIG. 25 may be applied to a machine learning system. The machine learning system may use various artificial neural network organization and processing models, such as a convolution neural network (CNN), a de-convolution neural network, a repeated neural network (RNN) selectively including a long short-term memory (LSTM) unit and/or gated recurrent unit (GRU), a stacked neural network (SNN), a state-space dynamic neural network (SSDNN), deep belief network (DBN), a generative adversarial network (GAN) and/or restricted Boltzmann machine (RBM).

Alternatively or additionally, such machine learning systems may include other types of machine learning models, for example, linear and/or logistic regression, statistics clustering, Bayesian classification, determination trees, dimensional reduction such as main component analyses, expert systems, and/or random forests; or a combination thereof. The machine learning models may be used to provide various services and/or applications. For example, an image classification service, a user authentication service based on biometric information or biometric data, an advanced driver assistance system (ADAS) service, a voice assistance service, an automatic speech recognition (ASR) service, etc. may be executed by an electronic device.

Various types of embodiments as follows may be suggested from some embodiments described above.

According to at least one example embodiment, the method of manufacturing the capacitor includes forming an interfacial layer on a first electrode layer, the first electrode layer including a nitride-based electrode; removing oxygen from the interfacial layer by reducing the interfacial layer; forming a dielectric layer on the interfacial layer that was reduced; and forming a second electrode layer on the dielectric layer.

In at least one example embodiment, the forming of the dielectric layer includes depositing the dielectric layer on the interfacial layer that was reduced, and crystallizing the dielectric layer that was deposited.

In at least one example embodiment, the crystallizing may be performed at a temperature of 500° C. to 700° C.

In at least one example embodiment, the depositing of the dielectric layer may be performed at a temperature of about 300° C. to about 400° C. under an oxygen atmosphere, the oxygen atmosphere including H₂O₂, H₂O, O₂ or O₃.

In at least one example embodiment, includes forming the dielectric layer such that the dielectric layer is 20% or less amorphous.

In at least one example embodiment, the reducing of the interfacial layer comprises performing a first thermal treatment on the interfacial layer.

In at least one example embodiment, the first thermal treatment may be performed under a first gas atmosphere and a first temperature.

In at least one example embodiment, the first gas atmosphere may include hydrogen and at least one of argon (Ar) or nitrogen (N₂).

In at least one example embodiment, the first temperature may be 500° C. to 700° C.

In at least one example embodiment, the dielectric layer may be formed to a thickness less than the dielectric layer.

In at least one example embodiment, the forming the dielectric layer includes oxidizing the interfacial layer that was reduced, and the dielectric layer is formed to a thickness such that the interfacial layer that was reduced is completely oxidized.

In at least one example embodiment, the forming the dielectric layer includes oxidizing the interfacial layer that was reduced, and the dielectric layer is formed to a thickness such that the interfacial layer that was reduced is partially oxidized.

In at least one example embodiment, the interfacial layer may include a first dielectric layer having a dielectric constant less than that of the dielectric layer.

In at least one example embodiment, the first dielectric layer may include at least one of Y₂O₃ or Sc₂O₃.

In at least one example embodiment, the dielectric layer may include a ternary oxide.

In at least one example embodiment, the ternary oxide may include at least one of SrTiO₃ (STO), BaTiO₃ (BTO), (BaₓSr₁₋ₓ)TiO₃ (BST), SrHfO₃, SrZrO₃, CaTiO₃ (CTO), or (CaₓSr₁₋ₓ)TiO₃ (CST).

In at least one example embodiment, the first electrode layer includes a first metal, the interfacial layer includes a second metal, and the second metal has a higher oxidation property than the first metal.

In at least one example embodiment, the first metal may include at least one of Ti, Nb, V, Mo, Mn, W, or Ru.

In at least one example embodiment, the second metal may include at least one of Y or Sc.

In at least one example embodiment, the interfacial layer may be formed to a thickness of 1 nanometers (nm) to 10 nm or 1 nm to 3 nm.

In at least one example embodiment, the dielectric layer may be formed to a thickness of 1 nm to 100 nm or 3 nm to 10 nm.

A capacitor according to at least one example embodiment includes a nitride-based lower electrode layer, an upper electrode layer; and a dielectric layer between the lower electrode layer and the upper electrode layer, the dielectric layer comprising a first dielectric layer in contact with the lower electrode layer, and a second dielectric layer on the first dielectric layer such that the first dielectric layer is between the second dielectric layer and the lower electrode layer, the second dielectric layer having a dielectric constant greater than a dielectric constant of the first dielectric layer, wherein the first dielectric layer is an interfacial layer, and the second dielectric layer is a crystallized layer and is 20% or less amorphous.

In at least one example embodiment, the first dielectric layer includes oxygen vacancies in a region adjacent to the lower electrode layer.

In at least one example embodiment, the first dielectric layer may be a completely oxidized layer, and may not include oxygen vacancies.

In at least one example embodiment, the lower electrode layer may include a first metal and the first dielectric layer may include a second metal having an oxidation property greater than the first metal. the first metal includes at least one of Ti, Nb, V, Mo, Mn, W, or Ru, and the second metal may include at least one of Y or Sc.

An electronic device according to at least one example embodiment includes a switching device, and a data storage element connected to the switching device, wherein the data storage element includes a nitride-based lower electrode layer connected to the switching device, an upper electrode layer, and a dielectric layer between the upper electrode layer and the lower electrode layer, the dielectric layer includes a first dielectric layer in contact with the lower electrode layer, and a second dielectric layer on the first dielectric layer such that the first dielectric layer is between the second dielectric layer and the lower electrode layer, the second dielectric layer having a dielectric constant greater than a dielectric constant of the first dielectric layer, the first dielectric layer is an interfacial layer, and the second dielectric layer is a crystallized layer and is 20% or less amorphous.

The method of manufacturing the capacitor including a nitride-based lower electrode layer disclosed herein includes performing a reduction thermal treatment on an interfacial layer formed on a lower electrode layer, and forming a high-k dielectric layer (e.g., STO layer) on the reduced interfacial layer. The reduced interfacial layer may include metal having a higher oxidation property than that of metal included in the lower electrode layer. Therefore, while the high-k oxide layer is formed, the re-oxidation on the reduced interfacial layer is performed first, and thus, the nitride-based lower electrode layer (e.g., TiN layer) covered by the reduced interfacial layer may be protected against the oxidation. Also, the interfacial layer may maintain the initial thickness thereof without regard to the thermal treatment for inducing reduction and a process of forming the high-k oxide layer. Also, the high-k oxide layer formed on the reduced interfacial layer may be mostly crystallized.

As a result, according to the method of manufacturing the capacitor, the oxidation of the nitride-based lower electrode layer, increase in the thickness of the dielectric layer, and degradation of the dielectric layer characteristics may be protected against during the processes of forming the high-k dielectric layer, and thus, the capacitance density of the capacitor may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a capacitor, the method comprising:
forming an interfacial layer on a first electrode layer, the first electrode layer including a nitride-based electrode;
removing oxygen from the interfacial layer by reducing the interfacial layer;
forming a dielectric layer on the interfacial layer that was reduced; and
forming a second electrode layer on the dielectric layer.

2. The method of claim 1, wherein the forming of the dielectric layer comprises:
depositing the dielectric layer on the interfacial layer that was reduced; and
crystallizing the dielectric layer that was deposited.

3. The method of claim 2, wherein the depositing of the dielectric layer is performed at a temperature of about 300° C. to about 400° C. under an oxygen atmosphere, the oxygen atmosphere including at least one of H₂O₂, H₂O, O₂ or O₃.

4. The method of claim 1, wherein the forming the dielectric layer includes forming the dielectric layer such that the dielectric layer is 20% or less amorphous.

5. The method of claim 1, wherein the reducing of the interfacial layer comprises performing a first thermal treatment on the interfacial layer.

6. The method of claim 5, wherein the first thermal treatment is executed under a gas atmosphere including hydrogen (H) and at least one of argon (Ar) or nitrogen (N₂).

7. The method of claim 1, wherein the forming the dielectric layer includes oxidizing the interfacial layer that was reduced, and the dielectric layer is formed to a thickness such that the interfacial layer that was reduced is completely oxidized.

8. The method of claim 1, wherein the forming the dielectric layer includes oxidizing the interfacial layer that was reduced, and the dielectric layer is formed to a thickness such that the interfacial layer that was reduced is partially oxidized.

9. The method of claim 1, wherein the interfacial layer includes a first dielectric layer having a dielectric constant less than a dielectric constant of the dielectric layer.

10. The method of claim 9, wherein the first dielectric layer includes at least one of Y₂O₃ or Sc₂O₃.

11. The method of claim 1, wherein the dielectric layer is a high-k dielectric layer, and includes at least one of SrTiO₃ (STO), BaTiO₃ (BTO), (BaₓSr₁₋ₓ)TiO₃ (BST), SrHfO₃, SrZrO₃, CaTiO₃ (CTO), or (CaₓSr₁₋ₓ)TiO₃ (CST).

12. The method of claim 1, wherein
the first electrode layer includes a first metal,
the interfacial layer includes a second metal, and
the second metal has a higher oxidation property than the first metal.

13. The method of claim 12, wherein the first metal includes at least one of Ti, Nb, V, Mo, Mn, W, or Ru.

14. The method of claim 12, wherein the second metal includes at least one of Y or Sc.

15. A capacitor comprising:
a lower electrode layer, the lower electrode layer including a nitride-based electrode;
an upper electrode layer; and
a dielectric layer between the lower electrode layer and the upper electrode layer, the dielectric layer comprising
a first dielectric layer in contact with the lower electrode layer, and
a second dielectric layer on the first dielectric layer such that the first dielectric layer is between the second dielectric layer and the lower electrode layer, the second dielectric layer having a dielectric constant greater than a dielectric constant of the first dielectric layer,
wherein the first dielectric layer is an interfacial layer, and
the second dielectric layer is a crystallized layer and is 20% or less amorphous.

16. The capacitor of claim 15, wherein the first dielectric layer includes oxygen vacancies in a region adjacent to the lower electrode layer.

17. The capacitor of claim 15, wherein the lower electrode layer includes a first metal,
the first dielectric layer includes a second metal, and
the second metal has an oxidation property greater than the first metal.

18. The capacitor of claim 17, wherein the first metal includes at least one of Ti, Nb, V, Mo, Mn, W, or Ru.

19. The capacitor of claim 17, wherein the second metal includes at least one of Y or Sc.

20. An electronic device comprising:
a switching device; and
a data storage element connected to the switching device,
wherein the data storage element comprises
a lower electrode layer connected to the switching device, the lower electrode layer nitride-based;
an upper electrode layer; and
a dielectric layer between the lower electrode layer and the upper electrode layer, the dielectric layer comprising
a first dielectric layer in contact with the lower electrode layer, and
a second dielectric layer on the first dielectric layer such that the first dielectric layer is between the second dielectric layer and the lower electrode layer, the second dielectric layer having a dielectric constant greater than a dielectric constant of the first dielectric layer,
wherein the first dielectric layer is an interfacial layer, and
the second dielectric layer is a crystallized layer and is 20% or less amorphous.
